(19) United States
(12) Patent Application Publication
(10) Pub. No.: US 2011/0180130 A1
(43) Pub. Date: Jul. 28, 2011

(54) Highly-conductive and textured front transparent electrode for a-si thin-film solar cells, and/or method of making the same

(75) Inventors: Alexey Krasnov, Canton, MI (US); Willem den Boer, Brighton, MI (US)

(73) Assignee: Guardian Industries Corp., Auburn Hills, MI (US)

(21) Appl. No.: 12/656,284

(22) Filed: Jan. 22, 2010

(51) Int. Cl. C23C 14/34; H01L 31/0264; H05K 13/00

(52) U.S. Cl. 136/256; 204/192.17; 29/592.1

(57) ABSTRACT

Certain example embodiments incorporate a “hybrid” design for the front electrode of solar cells, which advantageously combines naturally textured pyrolytic tin oxide and highly-conductive sputtered indium tin oxide (ITO). In certain example embodiments of this invention, a method of making a front electrode superstrate for a solar cell is provided. A glass substrate is provided. A layer of tin oxide is pyrolytically deposited on the glass substrate, with the layer of tin oxide being textured as a result of the pyrolytic deposition and with the layer of tin oxide being haze producing. A layer of indium tin oxide (ITO) is sputter-deposited on the layer of tin oxide, with the layer of ITO being generally conformal with respect to the layer of tin oxide. An amorphous silicon (a-Si) thin film layer stack is formed on the layer of ITO in making the front electrode superstrate.

### FIELD OF THE INVENTION

Certain example embodiments of this invention relate to solar cell devices, and/or methods of making the same. More particularly, certain example embodiments relate to a front transparent conductive electrode for solar cell devices (e.g., amorphous silicon or a-Si solar cell devices), and/or methods of making the same. Certain example embodiments incorporate a “hybrid” design for the front electrode, which advantageously combines naturally textured pyrolytic tin oxide and highly-conductive sputtered indium tin oxide (ITO).

### BACKGROUND AND SUMMARY OF EXAMPLE EMBODIMENTS OF THE INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon photovoltaic devices, for example, include a front electrode or contact. Typically, the transparent front electrode is made of a pyrolytic transparent conductive oxide (TCO) such as tin oxide formed on a transparent substrate such as a glass substrate. In many instances, the transparent front electrode is formed of a single layer using a method of chemical pyrolysis where precursors are sprayed onto the glass substrate at approximately 400 to 600 degrees C. Typical pyrolitic fluorine-doped tin oxide TCOs as front electrodes may be about 7000 nm thick, which provides for a sheet resistance (Rₛ) of about 10 ohms/square. To achieve high output power, a front electrode having a low sheet resistance and good ohmic contact to the cell top layer, and allowing maximum solar energy in certain desirable ranges into the absorbing semiconductor film, are desired.

Unfortunately, photovoltaic devices (e.g., solar cells) with only such conventional TCO front electrodes suffer from various problems.

First, a pyrolitic fluorine-doped tin oxide TCO about 7000 nm thick as the entire front electrode has a sheet resistance (Rₛ) of about 10 ohms/square which is rather high for the entire front electrode when used in large-size panels. A lower sheet resistance (and thus better conductivity) would be desired for the front electrode of a photovoltaic device. A lower sheet resistance may be achieved by increasing the thickness of such a TCO, but this will cause transmission of light through the TCO to drop thereby reducing output power of the photovoltaic device.

Second, conventional TCO front electrodes such as pyrolytic tin oxide allow a significant amount of infrared (IR) radiation to pass therethrough thereby allowing it to reach the semiconductor or absorbing layer(s) of the photovoltaic device. This IR radiation causes heat which increases the operating temperature of the photovoltaic device thereby decreasing the output power thereof.

Third, conventional flat TCO front electrodes such as non-textured pyrolytic tin oxide tend to reflect a significant amount of light in the region of from about 450-700 nm so that less than about 80% of useful solar energy reaches the semiconductor absorbing layer; this significant reflection of visible light is a waste of energy and leads to reduced photovoltaic module output power. Due to the TCO absorption and reflections of light which occur between the TCO (refractive index n about 1.8 to 2.0 at 550 nm) and the thin film semiconductor (n about 3.0 to 4.5), and between the TCO and the glass substrate (n about 1.5), the TCO coated glass at the front of the photovoltaic device typically allows less than 80% of the useful solar energy impinging upon the device to reach the semiconductor film which converts the light into electric energy.

Fourth, the rather high total thickness (e.g., 7000 nm in the case of a thick tin oxide TCO) of the front electrode, leads to high fabrication costs.

Fifth, the process window for forming a tin oxide TCO for a front electrode is both small and important. In this respect, even small changes in the process window can adversely affect conductivity of the TCO. When the TCO is the sole conductive layer of the front electrode, such adverse affects can be highly detrimental, which usually considerably affects the uniformity of electro-optical characteristics of the film.

Thus, it will be appreciated that there is a need in the art for improved front transparent contact for solar cell devices, and/or methods of making the same.

One aspect of certain example embodiments of this invention relates to a “hybrid” design for the front electrode, which advantageously combines naturally textured pyrolytic tin oxide and highly-conductive sputtered indium tin oxide (ITO).

In certain example embodiments of this invention, a method of making a front electrode superstrate for a solar cell is provided. A glass substrate is provided. A layer of tin oxide is pyrolytically deposited on the glass substrate, with the layer of tin oxide being textured as a result of the pyrolytic deposition and with the layer of tin oxide being haze producing. A layer of indium tin oxide (ITO) is sputter-deposited on the layer of tin oxide, with the layer of ITO being generally conformal with respect to the layer of tin oxide. An amorphous silicon (a-Si) thin film layer stack is formed on the layer of ITO in making the front electrode superstrate.

In certain example embodiments of this invention, a method of making a front electrode superstrate for a solar cell is provided. A glass substrate is provided. A layer of tin oxide is pyrolytically deposited on the glass substrate, with the layer of tin oxide being textured as a result of the pyrolytic deposition and with the layer of tin oxide being haze producing. At least one highly conductive layer is disposed on the layer of tin oxide, with the at least one highly conductive layer being generally conformal with respect to the layer of tin oxide. An amorphous silicon (a-Si) thin film layer stack is formed on the at least one highly conductive layer in making the front electrode superstrate. The at least one highly conductive layer comprises ITO, Ag, indium zinc oxide, AZO, indium gallium zinc oxide, and/or indium gallium oxide.

According to certain example embodiments, methods of making solar cells comprising such front electrode superstrates are provided. According to certain example embodiments, corresponding front electrode superstrates and corresponding solar cells also are provided.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 is a cross sectional view of an example photovoltaic device according to an example embodiment of this invention;

FIG. 2 is a cross sectional view of an example “hybrid” front contact in accordance with certain example embodiments of this invention; and

FIG. 3 is a flowchart illustrating an example process for making a “hybrid” front contact in accordance with certain example embodiments of this invention.

### DETAILED DESCRIPTION OF EXAMPLE EMBODIMENTS OF THE INVENTION

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices include three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices, this invention is not so limited and may be used in conjunction with other types of photovoltaic devices in certain instances including but not limited to devices including other types of semiconductor material, such as tandem thin-film solar cells.

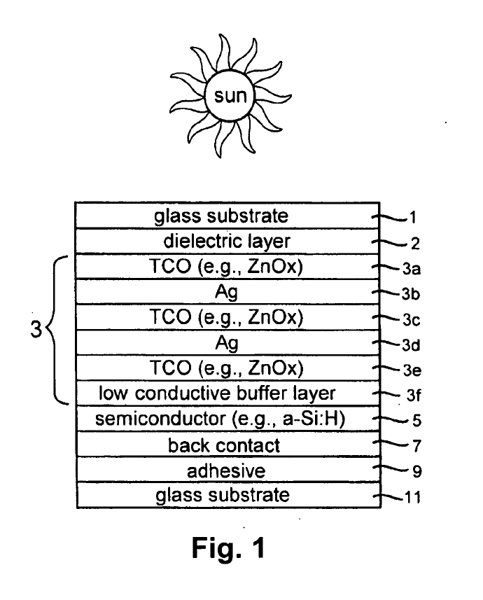

FIG. 1 is a cross sectional view of a photovoltaic device according to an example embodiment of this invention. The photovoltaic device includes transparent front glass substrate 1 (other suitable material may also be used for the substrate instead of glass in certain instances), optional dielectric layer(s) 2, multilayer front electrode 3, active semiconductor film 5 of or including one or more semiconductor layers (such as pin, pn, pinpin tandem layer stacks, or the like), back electrode/contact 7 which may be of a TCO or a metal, an optional encapsulant 9 or adhesive of a material such as ethyl vinyl acetate (EVA) or the like, and an optional superstrate 11 of a material such as glass. Of course, other layer(s) which are not shown may also be provided in the device. Front glass substrate 1 and/or rear superstrate (substrate) 11 may be made of soda-lime-silica based glass in certain example embodiments of this invention; and it may have low iron content and/or an antireflection coating thereon to optimize transmission in certain example instances. While substrates 1, 11 may be of glass in certain example embodiments of this invention, other materials such as quartz, plastics or the like may instead be used for substrate(s) 1 and/or 11. Moreover, superstrate 11 is optional in certain instances. Glass 1 and/or 11 may or may not be thermally tempered and/or patterned in certain example embodiments of this invention. Additionally, it will be appreciated that the word “on” as used herein covers both a layer being directly on and indirectly on something, with other layers possibly being located therebetween.

Dielectric layer(s) 2 may be of any substantially transparent material such as a metal oxide and/or nitride which has a refractive index of from about 1.5 to 2.5, more preferably from about 1.6 to 2.5, more preferably from about 1.6 to 2.2, more preferably from about 1.6 to 2.0, and most preferably from about 1.6 to 1.8. However, in certain situations, the dielectric layer 2 may have a refractive index (n) of from about 2.3 to 2.5. Example materials for dielectric layer 2 include silicon oxide, silicon nitride, silicon oxynitride, zinc oxide, tin oxide, titanium oxide (e.g., TiO₂), aluminum oxynitride, aluminum oxide, or mixtures thereof. Dielectric layer(s) 2 functions as a barrier layer in certain example embodiments of this invention, to reduce materials such as sodium from migrating outwardly from the glass substrate 1 and reaching the IR reflecting layer(s) and/or semiconductor. Moreover, dielectric layer 2 is material having a refractive index (n) in the range discussed above, in order to reduce visible light reflection and thus increase transmission of visible light (e.g., light from about 450-700 nm and/or 450-600 nm) through the coating and into the semiconductor 5 which leads to increased photovoltaic module output power.

Still referring to FIG. 1, multilayer front electrode 3 in the example embodiment shown in FIG. 1, which is provided for purposes of example only and is not intended to be limiting, includes from the glass substrate 1 outwardly first transparent conductive oxide (TCO) or dielectric layer 3a, first conductive substantially metallic IR reflecting layer 3b, second TCO 3c, second conductive substantially metallic IR reflecting layer 3d, third TCO 3e, and optional buffer layer 3f. Optionally, layer 3a may be a dielectric layer instead of a TCO in certain example instances and serve as a seed layer for the layer 3b. This multilayer film 3 makes up the front electrode in certain example embodiments of this invention. Of course, it is possible for certain layers of electrode 3 to be removed in certain alternative embodiments of this invention (e.g., one or more of layers 3a, 3c, 3d and/or 3e may be removed), and it is also possible for additional layers to be provided in the multilayer electrode 3. Front electrode 3 may be continuous across all or a substantial portion of glass substrate 1, or alternatively may be patterned into a desired design (e.g., stripes), in different example embodiments of this invention. Each of layers/films 1-3 is substantially transparent in certain example embodiments of this invention. The presence of IR reflecting layers is optional, however, as some solar cells may consider the incidence of at least near-IR advantageous.

In those example embodiments where it is advantageous to provide IR reflecting layers, first and second conductive substantially metallic IR reflecting layers 3b and 3d may be of or based on any suitable IR reflecting material such as silver, gold, or the like. These materials reflect significant amounts of IR radiation, thereby reducing the amount of IR which reaches the semiconductor film 5. Since IR increases the temperature of the device, the reduction of the amount of IR radiation reaching the semiconductor film 5 may in certain example instances be considered advantageous in that it reduces the operating temperature of the photovoltaic module so as to increase module output power. Moreover, the highly conductive nature of these substantially metallic layers 3b and/or 3d permits the conductivity of the overall electrode 3 to be increased. In certain example embodiments of this invention, the multilayer electrode 3 has a sheet resistance of less than or equal to about 12 ohms/square, more preferably less than or equal to about 9 ohms/square, and even more preferably less than or equal to about 6 ohms/square. Again, the increased conductivity (same as reduced sheet resistance) increases the overall photovoltaic module output power, by reducing resistive losses in the lateral direction in which current flows to be collected at the edge of cell segments. It is noted that first and second conductive substantially metallic IR reflecting layers 3b and 3d (as well as the other layers of the electrode 3) are thin enough so as to be substantially transparent to visible light. In certain example embodiments of this invention, first and/or second conductive substantially metallic IR reflecting layers 3b and/or 3d are each from about 3 to 12 nm thick, more preferably from about 5 to 10 nm thick, and most preferably from about 5 to 8 nm thick. In embodiments where one of the layers 3b or 3d is not used, then the remaining conductive substantially metallic IR reflecting layer may be from about 3 to 18 nm thick, more preferably from about 5 to 12 nm thick, and most preferably from about 6 to 11 nm thick in certain example embodiments of this invention. These thicknesses are desirable in that they permit the layers 3b and/or 3d to reflect significant amounts of IR radiation, while at the same time being substantially transparent to visible radiation which is permitted to reach the semiconductor 5 to be transformed by the photovoltaic device into electrical energy. The highly conductive IR reflecting layers 3b and 3d attribute to the overall conductivity of the electrode 3 much more than the TCO layers; this allows for expansion of the process window(s) of the TCO layer(s) which has a limited window area to achieve both high conductivity and transparency. Of course, as noted above, the presence of IR reflecting layers is optional, however, as some solar cells may consider the incidence of at least near-IR advantageous.

First, second, and third TCO layers 3a, 3c and 3e, respectively, may be of any suitable TCO material including but not limited to conducive forms of zinc oxide, zinc aluminum oxide, tin oxide, indium-tin-oxide, indium zinc oxide (which may or may not be doped with silver), or the like. These layers are typically substoichiometric so as to render them conductive as is known in the art. For example, these layers are made of material(s) which gives them a resistance of no more than about 10 ohm-cm (more preferably no more than about 1 ohm-cm, and most preferably no more than about 20 mohm-cm). One or more of these layers may be doped with other materials such as fluorine, aluminum, antimony or the like in certain example instances, so long as they remain conductive and substantially transparent to visible light. In certain example embodiments of this invention, TCO layers 3c and/or 3e are thicker than layer 3a (e.g., at least about 5 nm, more preferably at least about 10, and most preferably at least about 20 or 30 nm thicker). In certain example embodiments of this invention, TCO layer 3a is from about 3 to 80 nm thick, more preferably from about 5-30 nm thick, with an example thickness being about 10 nm. Optional layer 3a is provided mainly as a seeding layer for layer 3b and/or for antireflection purposes, and its conductivity is not as important as that of layers 3b-3e (thus, layer 3a may be a dielectric instead of a TCO in certain example embodiments). In certain example embodiments of this invention, TCO layer 3c is from about 20 to 150 nm thick, more preferably from about 40 to 120 nm thick, with an example thickness being about 74-75 nm. In certain example embodiments of this invention, TCO layer 3e is from about 20 to 180 nm thick, more preferably from about 40 to 130 nm thick, with an example thickness being about 94 or 115 nm. In certain example embodiments, part of layer 3e, e.g., from about 1-25 nm or 5-25 nm thick portion, at the interface between layers 3e and 5 may be replaced with a low conductivity high refractive index (n) film 3f such as titanium oxide to enhance transmission of light as well as to reduce back diffusion of generated electrical carriers; in this way performance may be further improved.

In certain example embodiments of this invention, the photovoltaic device may be made by providing glass substrate 1, and then depositing (e.g., via sputtering or any other suitable technique) multilayer electrode 3 on the substrate 1. Thereafter the structure including substrate 1 and front electrode 3 is coupled with the rest of the device in order to form the photovoltaic device shown in FIG. 1. For example, the semiconductor layer 5 may then be formed over the front electrode on substrate 1. Alternatively, the back contact 7 and semiconductor 5 may be fabricated/formed on substrate 11 (e.g., of glass or other suitable material) first; then the electrode 3 and dielectric 2 may be formed on semiconductor 5 and encapsulated by the substrate 1 via an adhesive such as EVA.

The alternating nature of the TCO layers 3a, 3c and/or 3e, and the conductive substantially metallic IR reflecting layers 3b and/or 3d, may sometimes also be considered advantageous in that it also one, two, three, four or all of the following advantages to be realized: (a) reduced sheet resistance (Rₛ) of the overall electrode 3 and thus increased conductivity and improved overall photovoltaic module output power; (b) increased reflection of infrared (IR) radiation by the electrode 3 thereby reducing the operating temperature of the semiconductor 5 portion of the photovoltaic module so as to increase module output power; (c) reduced reflection and increased transmission of light in the visible region of from about 450-700 nm (and/or 450-600 nm) by the front electrode 3 which leads to increased photovoltaic module output power; (d) reduced total thickness of the front electrode coating 3 which can reduce fabrication costs and/or time; and/or (e) an improved or enlarged process window in forming the TCO layer(s) because of the reduced impact of the TCO's conductivity on the overall electric properties of the module given the presence of the highly conductive substantially metallic layer(s). However, as noted above, the presence of the optional IR reflecting layers may not be advantageous in example solar cells may where the incidence of at least near-IR is desirable.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe may also be used for semiconductor film 5 in alternative embodiments of this invention.

Back contact, reflector and/or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with silver), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the superstrate 11. The metal portion may be closer to superstrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA or PVB. However, other materials such as Tedlar type plastic, Nuvasil type plastic, Tefzel type plastic or the like may instead be used for layer 9 in different instances.

As indicated above, the front transparent contact of a typical superstrate thin-film a-Si solar cell comprises a glass base (usually a soda-lime glass), coated with an optically transparent and electrically conducting film such as, for example, pyrolytic fluorine-doped tin oxide (FTO) or aluminum-doped zinc oxide (AZO). The choice of these two transparent conducting oxide (TCO) materials is related their ability to form a textured surface, either (1) naturally during the deposition or in-line, as in the case of FTO or low-pressure chemical vapor deposition (LPCVD) deposited AZO, or (2) after the deposition or off line, using texturing by chemical etching, as in case of sputtered AZO and in some instances where FTO is used, as well.

The desire for the front transparent electrode to be textured is determined by the low absorption coefficient of the Si absorber of the thin-film solar cell. If the solar light passes only twice through the absorber (e.g., on the way to and from the back reflective contact), a large number of photons often may escape the absorber without generating the electron-hole pairs. To absorb more photons by the absorber, the TCO layer may be textured to scatter the light at sufficient angles to promote multiple “bouncing” of photons within the absorber, thereby generating more electrical carriers and increasing the efficiency of the solar cell.

Each of the above-mentioned techniques for producing a textured TCO has its attendant advantages and drawbacks. For example, the commonly used pyrolytic FTO is relatively inexpensive to produce, provides good light scattering, and can be deposited in-line by spaying chemical precursors on a hot glass surface. The pyrolytically deposited SnO₂:F typically is “naturally” textured during its deposition. Disadvantages of the FTO relate to the typical need to produce a thick film in order to achieve acceptably low sheet resistance, as well as the optical and electrical uniformity issues of the fluorine-doped film.

One disadvantage of LPCVD deposited AZO is that the carrier mobility of the material is relatively low. The low carrier mobility typically means that films with thicknesses in excess of 1 micron are needed, e.g., to provide sufficiently low sheet resistance. The thick coatings, in turn, cause a large of amount of light absorption.

Sputtered and off-line textured AZO has an advantage of producing large crater-like features. These features are considered to have an advantage in scattering longer wavelengths of light. At the same time, the insufficient conductivity of the material (e.g., especially of that deposited without intentionally heating the glass substrate) typically requires either the use of thicker films or the application of an additional underlayer, such as a highly-conductive ITO or Ag (as discussed, for example, in co-pending and commonly assigned application Ser. No. 12/591,061, the entire contents of which are hereby incorporated herein by reference). The use of textured AZO also requires an expensive step of chemical etching in the production process.

The efficiency of a-Si modules sometimes may be increased by 20% via surface texturing of the transparent conductor on which the a-Si semiconductor is deposited for the effective light scattering into the semiconductor layer of the device. However, this chemical etching may sometimes introduce further costs and process complexities.

To overcome some of these and/or other drawbacks and/or improve these and/or other techniques, certain example embodiments relate to an alternative hybrid TCO design in which the high conductivity of off-line sputter deposited ITO is combined with the natural texture of in-line pyrolytically-deposited tin oxide (e.g., SnO₂ or other suitable stoichiometry). This hybrid approach may be used in connection with the above-described and/or other example implementations for solar cells, at least inasmuch as certain example embodiments relate to an improved front transparent conductive electrode for solar cell devices (e.g., amorphous silicon or a-Si solar cell devices), and/or methods of making the same.

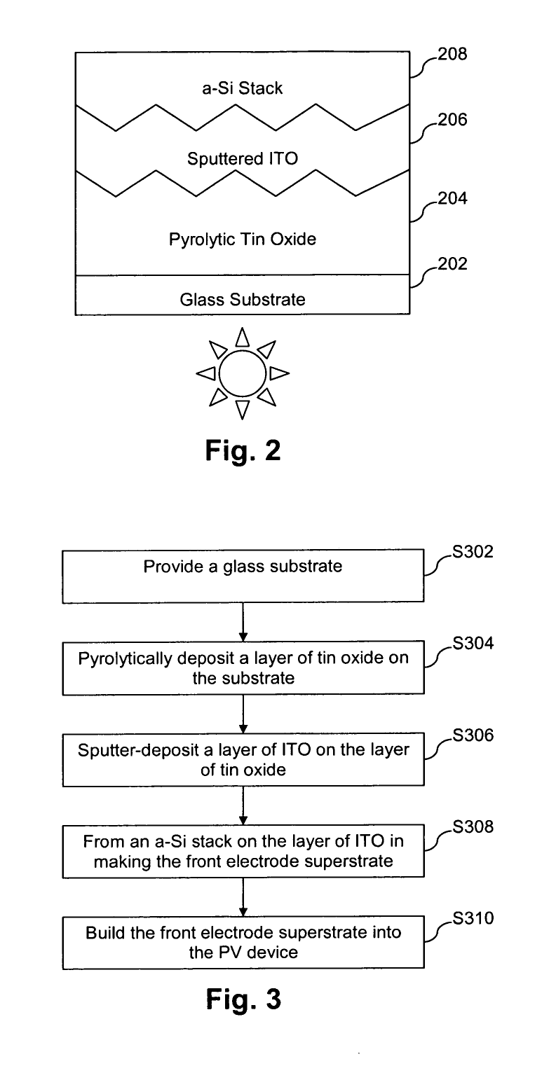

FIG. 2 is a cross sectional view of an example “hybrid” front contact in accordance with certain example embodiments, and FIG. 3 is a flowchart illustrating an example process for making a “hybrid” front contact in accordance with certain example embodiments of this invention. A glass substrate 202 that serves as the superstrate for the front electrode is provided (step S302). A layer of tin oxide 204 is then pyrolytically deposited on the substrate 202 (step 304). The layer of tin oxide 204 is naturally textured by virtue of the pyrolytic deposition process. A layer of ITO 206 is then sputter-deposited, directly or indirectly, on the layer of tin oxide (step 306). This layer of ITO 206 also will be textured, as the sputtering of the ITO will yield a layer that is generally or substantially conformal with respect to the underlying naturally textured pyrolytic tin oxide layer 204. An a-Si or other suitable semiconductor stack 208 is formed atop the layer of sputtered ITO 206 (step 308) in making the front electrode superstrate. This front electrode superstrate may then be built into the photovoltaic device (step 310) in certain example embodiments.

The tin oxide underlayer of certain example embodiments does not need to be thick. In fact, the minimum thickness required to produce a textured layer with sufficient haze is acceptable in certain example implementations. This advantageously may reduce the cost of the overall coating. The tin oxide underlayer also does not need to be fluorine-doped or otherwise doped in example implementations, as the tin oxide underlayer does not need to be conductive in all example embodiments. Indeed, the primary purpose of this underlayer in certain example embodiments merely is to create texture with proven light scattering capability. The fact that the tin oxide does not need to be doped further reduces its light absorption in example implementations where dopants are lacking, which may further promote performance of the solar cell. Additionally, it will be appreciated that the deposition of the undoped tin oxide may be performed in-line in certain example embodiments, thereby reducing or completely eliminating the need for chemical etch-texturing processes without having to introduce any additional manufacturing process steps. This also may improve throughput and reduces the overall cost of the coating.

In certain cases where the pyrolytic tin oxide layer is non-conductive, the pyrolytic tin oxide layer may be thought of as being different from the overall electrode structure (e.g., different from electrode 3 in the FIG. 1 example embodiment), whereas the electrode itself may comprise or consist of the sputtered ITO. In fact, the pyrolytic tin oxide layer may even be provided as a part of a dielectric coating in certain example instances provided that its sheet resistance is sufficiently high and/or its conductivity sufficiently low.

Of course, a doped and/or textured tin oxide layer may be provided in connection with certain example embodiments. In those embodiments where the tin oxide is textured (or further textured), such texturing may be performed in-line or off-line in different example implementations of this invention, e.g., by chemical etching, ion beam roughening, etc. In any event, the introduction of a less expensive tin oxide may reduce and sometimes even completely eliminate the need for conductive AZO. Furthermore, the introduction of the highly-conductive ITO may improve the performance of the hybrid TCO as compared to a pure tin oxide coating.

Although certain example embodiments have been described as having a layer of ITO, other transparent conductive coatings may be used in place of or in addition to the sputter-deposited ITO. Such a highly-conductive TCO layer may be located on top of the textured pyrolytic tin oxide in place of, or in addition to, the sputter-deposited ITO. Further and/or alternate materials suitable for inclusion in certain example embodiments include, for example, Ag-based layers, ITO/Ag combinations (e.g., see the FIG. 1 example), indium zinc oxide, AZO, indium gallium zinc oxide, indium gallium oxide, and/or combinations thereof. Similarly, in certain example embodiments, any highly-conductive TCO layer may be deposited by virtually any deposition process other than sputtering in place of or in addition to the sputtered ITO layer. Such deposition process may include, for example, chemical pyrolysis, atomic-layer deposition, etc. In general, however, certain example embodiments incorporate a thin, naturally-textured tin oxide in combination with a single- or multi-layer TCO, e.g., ITO, and its combination with a buffer layer between the ITO and the semiconductor. Adopting this general approach is advantageous in that certain example embodiments may reduce the need for and/or sometimes even completely eliminate the need for a wet-texturing process, e.g., by virtue of incorporating naturally-textured tin oxide.

An intentionally heated substrate may be used during the ITO deposition to activate its electrical conductivity and/or improve the optical transmission in certain example instances. Furthermore, post-deposition baking processes may be used in certain example instances to activate the electrical conductivity and/or improve the optical transmission of the sputter-deposited ITO.

Buffer layers, such as optically or electrically matching layers or diffusion blocking layers or layer stacks, may be provided at one or all of the interfaces of the hybrid coating. Such buffer layers may include, for example, silicon oxide, silicon nitride, silicon oxinitride, and/or the like.

In certain example embodiments, the dielectric layer 2 may be a single layer or a multi-layer stack. The dielectric layer or dielectric layer stack may be provided directly on the glass substrate. For example, in certain example embodiments, the dielectric layer 2 may comprise titanium oxide, silicon oxide, silicon nitride, silicon oxynitride, zirconium oxide, and/or the like. Indeed, any transparent or partially transparent dielectric layer may be used in different example embodiments of this invention, alone or in a layer stack with the same or different dielectric layers. If a titanium oxide layer is provided, it may in certain example embodiments have a thickness of 0-30 nm, more preferably 5-20 nm, still more preferably 5-10 nm, and sometimes about 7 nm. An example titanium oxide dielectric layer may have a refractive index of about 2.2-2.6, and sometimes 2.4. If a silicon oxynitride layer is provided, it may in certain example embodiments have a refractive index of 1.5-2.5, more preferably 1.6-2.2, and sometimes about 1.6 or 1.7. Furthermore, if a silicon oxynitride layer is provided, it may in certain example embodiments have a thickness of 0-80 nm, more preferably 10-50 nm, still more preferably 20-40 nm, still more preferably 25-35 nm, and sometimes about 30 nm.

In certain example embodiments, the thickness ranges of the pyrolytic tin oxide may be 100-1000 nm, more preferably 200-600 nm, and sometimes about 300 nm. The refractive index for such a layer may be 1.7-2.1, more preferably 1.9-2.0, and sometimes 1.95 in certain example embodiments, and the photopic haze in certain example embodiments may be 8-30%, more preferably 12-24%, and sometimes 16%. In certain example embodiments, the total thickness ranges of the ITO overcoat or other TCO layer or TCO layer stack (e.g., in accordance with those materials identified above) may be 100-1000 nm, more preferably 200-800 nm, and sometimes 300 nm, and the refractive index of certain example embodiments may be 1.7-2.1, more preferably 1.9-2.0, and sometimes 1.95 (e.g., so that it matches or substantially matches the refractive index of the pyrolytic tin oxide layer).

As alluded to above, in certain example embodiments, the entire contact assembly may be post-deposition baked and/or heat treated. Such baking and/or heat treating in certain example embodiments may be performed at a temperature of 200-550 degrees C., more preferably about 400 degrees C. The baking and/or heat treating may be performed in certain example embodiments for 1-30 minutes, more preferably 10-30 minutes. Such baking and/or heat treating advantageously may help increase transmission and conductivity, e.g., by making some or all of the layers more crystallized. Baking and/or heat treating may be performed before or after the etching when etching is implemented, in different embodiments of this invention.

Any suitable semiconductor may be used in connection with different embodiments of this invention. For example, certain example embodiments may relate to an a-Si single-junction solar cell, a single-junction microcrystalline silicon (mc-Si) solar cell, an a-Si tandem-junction solar cell, and/or the like.

Any suitable transparent substrate may be used in connection with certain example embodiments of this invention. For instance, certain example embodiments may incorporate a low-iron glass substrate, e.g., to help ensure that as much red and near-IR light as possible is transferred to the semiconductor absorber layer. Example low-iron glass substrates are disclosed, for example, in co-pending and commonly assigned application Ser. Nos. 11/049,292; 11/122,218; 11/373,490; 12/073,562; 12/292,346; 12/385,318; and 12/453,275, the entire contents of each of which are hereby incorporated herein by reference.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making a front electrode superstrate for a solar cell, the method comprising:
providing a glass substrate;
pyrolytically depositing a layer of tin oxide on the glass substrate, the layer of tin oxide being textured as a result of the pyrolytic deposition and being haze producing;
sputter-depositing a layer of indium tin oxide (ITO) on the layer of tin oxide, the layer of ITO being generally conformal with respect to the layer of tin oxide; and
forming an amorphous silicon (a-Si) thin film layer stack on the layer of ITO in making the front electrode superstrate.

2. The method of claim 1, wherein the layer of tin oxide is not doped.

3. The method of claim 2, wherein the layer of tin oxide is non-conductive compared to the layer of ITO.

4. The method of claim 2, wherein the pyrolytic depositing of the tin oxide is performed via an in-line process.

5. The method of claim 1, wherein the layer of tin oxide is fluorine-doped tin oxide.

6. The method of claim 5, further comprising texturing the layer of fluorine-doped tin oxide.

7. The method of claim 6, wherein the texturing is performed by chemical etching.

8. The method of claim 6, wherein the texturing is performed by ion-beam roughening.

9. The method of claim 6, wherein the texturing is performed via an in-line process.

10. The method of claim 6, wherein the texturing is performed by an off-line process.

11. The method of claim 1, wherein the layer of ITO directly contacts the layer of tin oxide.

12. The method of claim 1, further comprising heating the substrate during the sputter-depositing of the layer of ITO to activate the electrical conductivity and/or improve the optical transmission of the layer of ITO.

13. The method of claim 1, further comprising post-deposition baking the substrate with the layer of ITO sputter-deposited thereon to activate the electrical conductivity and/or improve the optical transmission of the layer of ITO.

14. The method of claim 1, further comprising providing at least one highly conductive layer adjacent the layer of ITO, the at least one highly conductive layer including Ag, indium zinc oxide, AZO, indium gallium zinc oxide, and/or indium gallium oxide.

15. A method of making a solar cell, the method comprising:
providing a front electrode superstrate according to claim 1; and
building the front electrode superstrate into the solar cell.

16. A front electrode superstrate for a solar cell, comprising:
a glass substrate;
a pyrolytically deposited layer of tin oxide on the glass substrate, the layer of tin oxide being textured as a result of the pyrolytic deposition;
a layer of sputter-deposited indium tin oxide (ITO) on the layer of tin oxide, the layer of ITO being generally conformal with respect to the layer of tin oxide; and
an amorphous silicon (a-Si) thin film layer stack formed on the layer of ITO.

17. A solar cell, comprising the front electrode superstrate of claim 16.

18. A method of making a front electrode superstrate for a solar cell, the method comprising:
providing a glass substrate;
pyrolytically depositing a layer of tin oxide on the glass substrate, the layer of tin oxide being textured as a result of the pyrolytic deposition and being haze producing;
disposing at least one highly conductive layer on the layer of tin oxide, the at least one highly conductive layer being generally conformal with respect to the layer of tin oxide; and
forming an amorphous silicon (a-Si) thin film layer stack on the at least one highly conductive layer in making the front electrode superstrate,
wherein the at least one highly conductive layer comprises ITO, Ag, indium zinc oxide, AZO, indium gallium zinc oxide, and/or indium gallium oxide.

19. The method of claim 18, wherein the at least one highly conductive layer is sputter-deposited.

20. The method of claim 18, wherein each step in the method is performed in-line.
